(19) United States
(12) Patent Application Publication
(10) Pub. No.: US 2025/0250454 A1
(43) Pub. Date: Aug. 7, 2025

(54) MXene SURFACE-MODIFIED WITH METAL ALKOXIDE AND PREPARATION METHOD THEREOF

(71) Applicant: KOREA INSTITUTE OF SCIENCE AND TECHNOLOGY, Seoul (KR)

(72) Inventors: Seon Joon KIM, Seoul (KR); Seung Sang HWANG, Seoul (KR); Albert LEE, Seoul (KR); Tae Gon OH, Seoul (KR); Tae Yun KO, Seoul (KR); Seong Eun LEE, Seoul (KR)

(73) Assignee: KOREA INSTITUTE OF SCIENCE AND TECHNOLOGY, Seoul (KR)

(21) Appl. No.: 19/184,765

(22) Filed: Apr. 21, 2025

Related U.S. Application Data
(63) Continuation of application No. PCT/KR2024/006448, filed on May 13, 2024.

(30) Foreign Application Priority Data
Dec. 11, 2023 (KR) 10-2023-0179112

(51) Int. Cl. C09D 11/52; C09C 1/44; C09C 3/08; C09D 11/033; C09D 11/037

(52) U.S. Cl. CPC C09D 11/52; C09C 1/44; C09C 3/08; C09D 11/033; C09D 11/037; C01P 2006/40

(57) ABSTRACT

The present invention discloses a MXene surface-modified with a metal alkoxide, which is formed by surface-modifying a MXene represented by the following Chemical Formula 1 with a metal alkoxide, in which the metal alkoxide is covalently bonded to the surface of the MXene and is present as a ligand.

Mₙ₊₁ Xₙ [Chemical Formula 1]

Here, M is one or more transition metal elements selected from the group consisting of Sc, Ti, V, Cr, Mn, Y, Zr, Nb, Mo, Hf, and Ta, X is at least one of carbon and nitrogen, and n is an integer from 1 to 4.

### CROSS-REFERENCE TO RELATED APPLICATIONS

This application is a continuation of International Application No. PCT/KR2024/006448 filed on May 13, 2024, which claims the benefit of Korean Patent Application No. 10-2023-0179112 filed on Dec. 11, 2023, in the Korean Intellectual Property Office, the entire disclosures of which are incorporated herein by reference for all purposes.

### TECHNICAL FIELD

The present invention relates to a MXene surface-modified with a metal alkoxide and dispersed in polar organic solvents as well as non-polar organic solvents, a method for preparing the same, and a use thereof.

### BACKGROUND ART

A MXene is a ceramic material with a two-dimensional planar structure in which carbon or nitrogen is bonded to a transition metal. A process of converting a 3D MAX phase into a 2D MXene involves an etching process using a strong acid. As a result of the above etching process, an end group such as a hydroxyl group (OH) and an oxidation group (—O) remains on the surface of MXene. Therefore, MXene has been highlighted as a material that has electrical conductivity due to a transition metal and simultaneously has hydrophilicity due to the functional groups present at its ends.

In order to apply the MXene having hydrophilicity to a variety of industries, studies have been currently actively conducted to disperse MXene in various types of organic solvents. In particular, the development of high-performance MXene materials that are stably dispersed in various organic solvents while maintaining high electrical conductivity remains a challenging task to date. Further, there is a need for developing technology to prepare an organic dispersion ink which is optimized for conductive ink-based industries such as the printing industry and battery industry from MXene.

The MXene organic inks developed to date are mainly dispersed in polar organic solvents, and in this case, the electrical conductivity thereof has a level of several tens to several thousands of S/cm. However, for application in a broader range of industries, the MXene organic ink needs to be dispersed in a non-polar organic solvent. A MXene ink dispersed in a non-polar organic solvent exhibits electrical conductivity at a level of several tens to several hundreds of S/cm, and has significantly lower electrical conductivity characteristics than that when dispersed in a polar organic solvent.

### DISCLOSURE

### Technical Problem

To solve the aforementioned problems, an object of the present invention is to provide a MXene which is stably dispersible not only in a polar organic solvent but also in a non-polar organic solvent, and a method for preparing the same.

To solve the aforementioned problems, another object of the present invention is to provide a MXene that exhibits a higher level of electrical conductivity than MXenes in the related art even in a non-polar organic solvent, and a method for preparing the same.

In addition, the present invention intends to provide a conductive film and a polymer composite using the MXene.

In addition, the present invention intends to provide an electromagnetic wave shielding material produced based on a conductive film and a polymer composite using the MXene.

### Technical Solution

To achieve the objects of the present invention as described above, the present invention discloses a MXene surface-modified with a metal alkoxide, which is formed by surface-modifying a MXene represented by the following Chemical Formula 1 with a metal alkoxide, in which the alkoxide is covalently bonded to the surface of the MXene and is present as a ligand.

Mₙ₊₁Xₙ [Chemical Formula 1]

Here, M is one or more transition metal elements selected from the group consisting of Sc, Ti, V, Cr, Mn, Y, Zr, Nb, Mo, Hf, and Ta, X is at least one of carbon (C) and nitrogen (N), and n is an integer from 1 to 4.

The metal of the metal alkoxide includes an alkali metal. In addition, the alkyl group or aryl group of the alkoxide may be in the form of a carbon chain or a carbon ring, and the alkoxide may further include an element selected from the group consisting of halogen elements (F, Cl, Br, and I), nitrogen (N), sulfur (S), and silicon (Si).

A method for preparing a MXene surface-modified with a metal alkoxide includes: preparing a MXene solution dispersed in a first solvent; introducing a metal alkoxide into a second solvent and stirring the resulting mixture; and modifying the surface of MXene with the metal alkoxide by mixing solutions produced in the preparing step and the stirring step and stirring the resulting mixture for a predetermined time or more.

The first solvent and the second solvent include at least one selected from the group consisting of dimethyl sulfoxide (DMSO), dimethylformamide (DMF), N-methyl-2-pyrrolidone (NMP), propylene carbonate (PC), toluene, and hexane.

After the modifying step, dispersing the metal alkoxide-surface-modified MXene in an organic solvent selected from the group consisting of ethyl alcohol, isopropyl alcohol, acetonitrile, acetone, ethyl acetoacetate, diethyl ether, chloroform, toluene, and dichlorobenzene to obtain a MXene organic ink is further performed.

The concentration of the MXene solution in the preparing step ranges from 0.01 to 100 mg/mL.

When the amount of the MXene is x mg, the amount of metal alkoxide used in the stirring step is

$$\frac{1}{30} x μ l$$

to 100x μl.

The stirring time in the stirring step ranges from 1 to 300 minutes, and the stirring temperature is 60° C. or less.

The present invention discloses a MXene organic ink including an organic solvent in which the MXene is dispersed, the organic solvent being selected from the group consisting of ethyl alcohol, isopropyl alcohol, acetonitrile, acetone, ethyl acetoacetate, diethyl ether, chloroform, toluene, and dichlorobenzene.

The concentration of the MXene organic ink is 0.01 to 100 mg/mL.

A method for preparing a MXene organic ink is disclosed, the method including dispersing a MXene surface-modified with a metal alkoxide in an organic solvent, in which the organic solvent is selected from the group consisting of ethyl alcohol, isopropyl alcohol, acetonitrile, acetone, ethyl acetoacetate, diethyl ether, chloroform, toluene, and dichlorobenzene.

Disclosed is an electrically conductive film including the MXene organic ink, which is prepared by a liquid process.

Disclosed is an electrically conductive polymer composite including the MXene organic ink.

Disclosed is an electromagnetic wave shielding material prepared using the electrically conductive film or the electrically conductive polymer composite.

### Advantageous Effects

The effects of the present invention obtained through the above-described means for solution are as follows.

The MXene proposed by the present invention has a surface modified with a metal alkoxide that is readily commercially available, and thus can be stably dispersed in not only a polar solvent, but also a non-polar organic solvent.

In addition, the surface-modified MXene proposed by the present invention exhibits a higher level of electrical conductivity than MXenes in the related art even in a non-polar organic solvent.

In addition, the surface-modified MXene proposed by the present invention can be used as an electromagnetic wave shielding material through conductive film and polymer composite forms.

Since the MXene organic ink proposed by the present invention can be stably dispersed in not only a polar organic solvent but also a non-polar organic solvent, the MXene organic ink can be used in a customized manner for industry groups that require various types of organic dispersion inks.

### DESCRIPTION OF DRAWINGS

FIG. 1 is a conceptual view illustrating a process of modifying the surface of MXene with a metal alkoxide according to one embodiment of the present invention.

FIG. 2 is a conceptual view illustrating a reaction for modifying the surface of MXene with a metal alkoxide according to one embodiment of the present invention.

FIG. 3 illustrates inks in which MXene modified with a metal alkoxide according to one embodiment of the present invention is dispersed in various organic solvents.

FIG. 4 illustrates examples of metal alkoxides for modifying the surface of MXene according to one embodiment of the present invention.

FIG. 5 is a flow chart illustrating a process of preparing a MXene surface-modified with a metal alkoxide according to one embodiment of the present invention.

FIG. 6 is a conceptual view for describing a reaction mechanism for modifying the surface of a MXene with a metal alkoxide according to one embodiment of the present invention.

FIG. 7 is a photograph measuring the electrical conductivity of a MXene surface-modified with ethoxide according to one embodiment of the present invention.

FIG. 8 is a graph illustrating the electrical conductivity of a MXene surface-modified with sodium ethoxide (NaOEt) according to one embodiment of the present invention, when the MXene is dispersed in a toluene solvent, according to the amount of NaOEt.

### MODE FOR DISCLOSURE

Hereinafter, a MXene surface-modified with a metal alkoxide and a method for preparing the same related to the present invention will be described in more detail with reference to drawings.

In the present specification, like reference numbers are used to designate like constituents even though they are in different Examples, and the description thereof will be omitted.

When it is determined that the detailed description of the publicly known art related in describing the Examples disclosed in the present specification may obscure the gist of the Examples disclosed in the present specification, the detailed description thereof will be omitted.

The accompanying drawings are provided to easily understand the Examples disclosed in the present specification, and it is to be appreciated that the technical spirit disclosed in the present specification is not limited by the accompanying drawings, and the accompanying drawings include all the modifications, equivalents, and substitutions included in the spirit and the technical scope of the present invention.

In the following description, singular expressions include plural expressions unless the context clearly indicates otherwise.

In the present application, the term “include” or “have” is intended to indicate the presence of a characteristic, number, step, operation, constituent element, part or any combination thereof described in the specification, and it should be understood that the possibility of the presence or addition of one or more other characteristics or numbers, steps, operations, constituent elements, parts or any combination thereof is not precluded.

Hereinafter, a MXene surface-modified with a metal alkoxide and a method for preparing the same related to the present invention will be described in more detail with reference to drawings.

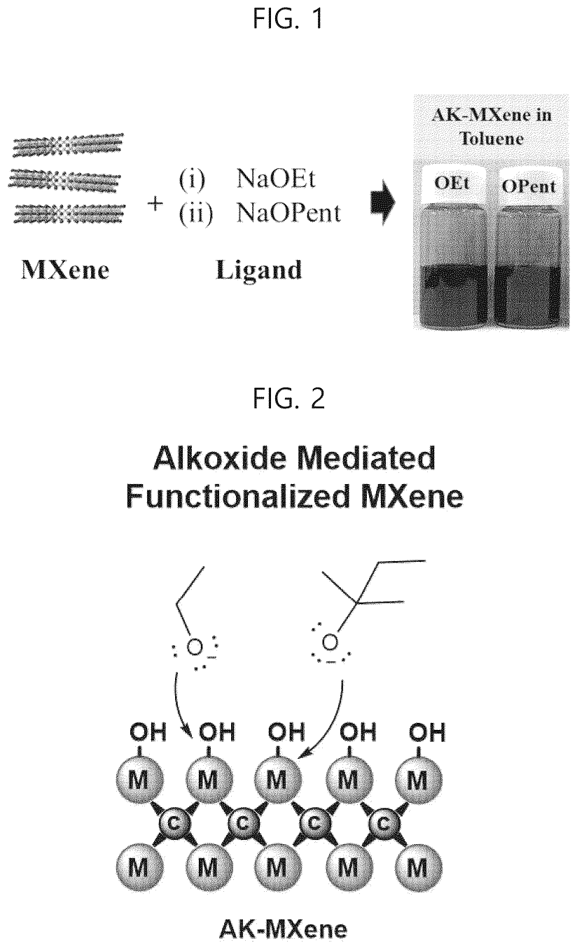

FIG. 1 is a conceptual view illustrating a process of modifying the surface of MXene with a metal alkoxide according to one embodiment of the present invention, and FIG. 2 is a conceptual view illustrating a reaction for modifying the surface of MXene with a metal alkoxide according to one embodiment of the present invention. Hereinafter, the present invention will be described in more detail with reference to FIGS. 1 and 2.

The MXene surface-modified with a metal alkoxide according to one embodiment of the present invention is formed by surface-modifying a MXene represented by the following Chemical Formula 1 with a metal alkoxide.

Mₙ₊₁Xₙ [Chemical Formula 1]

Here, M is one or more transition metal elements selected from the group consisting of Sc, Ti, V, Cr, Mn, Y, Zr, Nb, Mo, Hf, and Ta, X is at least one of carbon and nitrogen, and n is an integer from 1 to 4.

If there are two transition metal elements, one of the transition metal elements may be represented as Ma, and the other transition metal element may be represented as Mb, and Chemical Formula 1 may be represented as (Ma_{(1-y)}Mb_{y})ₙ₊₁Xₙ.

Mₙ₊₁ may include, for example, Ti₃, Nb₄, Mo₂, V₂, Cr₂, Sc₂, Mo₂Ti, Cr₂Ti, Nb₂Ti, TiNb, and TiZr, but is not limited thereto.

The metal alkoxide provides a ligand that is present on the surface of the surface-modified MXene. In this case, examples of the metal alkoxide include NaOEt and NaOPent. The MXene surface-modified with the alkoxide ligand is well dispersed even in a non-polar solvent such as toluene, which can be confirmed in the photograph in FIG. 1.

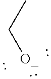

of FIG. 2 illustrates ethoxide (—OEt) which is in the form of anion when NaOEt in (i) of FIG. 1 reacts, and

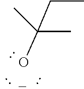

of FIG. 2 illustrates tert-pentoxide (—OPent) which is in the form of anion when NaOPent in (ii) of FIG. 1 reacts.

M and C illustrated in FIG. 2 represent a transition metal of MXene and oxygen, respectively. A —OH group (hydroxy group) is any surface functional group, and in addition to the —OH group, other functional groups such as an oxidation group (—O) may be attached.

As illustrated by the arrows in FIG. 2, the unshared electron pairs of the oxygen atoms of ethoxide and tert-pentoxide attack the metal (M) moiety of MXene to be covalently bonded to the surface of the MXene.

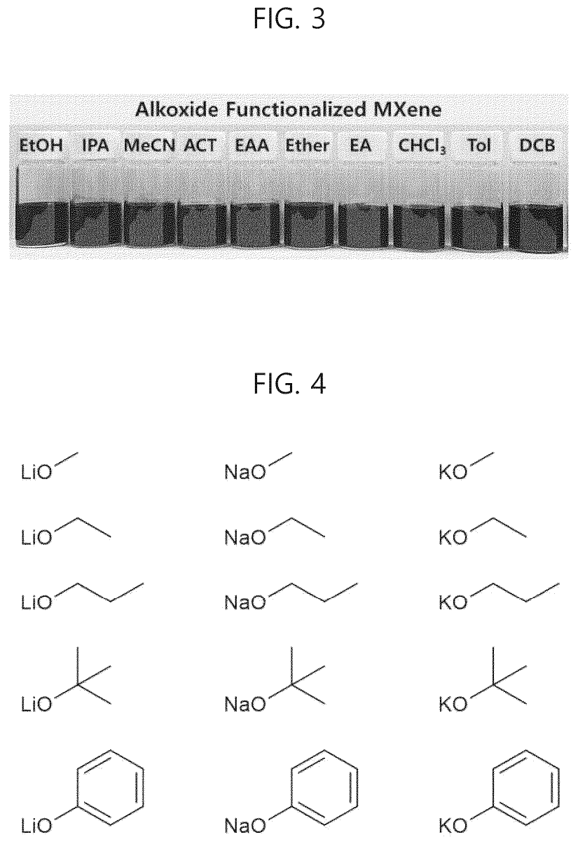

FIG. 3 illustrates inks in which MXene modified with a metal alkoxide according to one embodiment of the present invention is dispersed in various organic solvents. The organic solvents shown in FIG. 3 are as follows.
EtOH: ethyl alcohol
IPA: isopropyl alcohol
MeCN: acetonitrile
ACT: acetone
EAA: ethyl acetoacetate
Ether: diethyl ether
CHCl₃: chloroform
Tol: toluene
DCB: dichlorobenzene

A process of converting a 3D MAX phase into a 2D MXene involves an etching process using a strong acid. As a result of the above etching process, an end group such as a hydroxyl group (OH) and an oxidation group (—O) remains on the surface of MXene. Therefore, the end groups enable the MXene to have hydrophilicity, and it is known that the MXene has the characteristic of being well dispersed in polar solvents.

Furthermore, the present invention has the characteristics in that by modifying the surface of MXene with a metal alkoxide, the MXene is well dispersed even in non-polar solvents due to the hydrophobicity of the alkoxide group covalently bonded to the surface of the MXene. Referring to FIG. 3, it can be confirmed that MXene surface-modified with a metal alkoxide is well dispersed in various polar solvents as well as non-polar solvents.

Further, since metal alkoxides are readily commercially available, the present invention has an advantage in the surface modification process of MXene.

FIG. 4 illustrates examples of metal alkoxides for modifying the surface of MXene according to one embodiment of the present invention.

In one embodiment, the metal of the metal alkoxide may include an alkali metal. The alkali metal may be selected from the group consisting of lithium (Li), sodium (Na), potassium (K), rubidium (Rb), cesium (Cscesium), and francium (Fr). FIG. 4 illustrates lithium (Li), sodium (Na), and potassium (K) as an example of the alkali metal.

In one embodiment, the alkyl group or aryl group of the metal alkoxide is in the form of a carbon chain or a ring. In addition, the metal alkoxide may further include an element selected from the group consisting of a halogen element, nitrogen, sulfur, and silicon.

In addition, examples of the alkoxide group disclosed in the present invention include methoxide, ethoxide, propoxide, butoxide, pentoxide, and phenoxide (phenolate), as illustrated in FIG. 4.

In addition, instead of the alkoxide group disclosed in the present invention, an enolate anion having both the characteristics of an alkoxide and a carbanion can also be used. When the electrons of the enolate anions are concentrated toward an oxygen atom, the surface modification reaction disclosed in the present invention may occur.

Hereinafter, a method for preparing a MXene surface-modified with a metal alkoxide will be described.

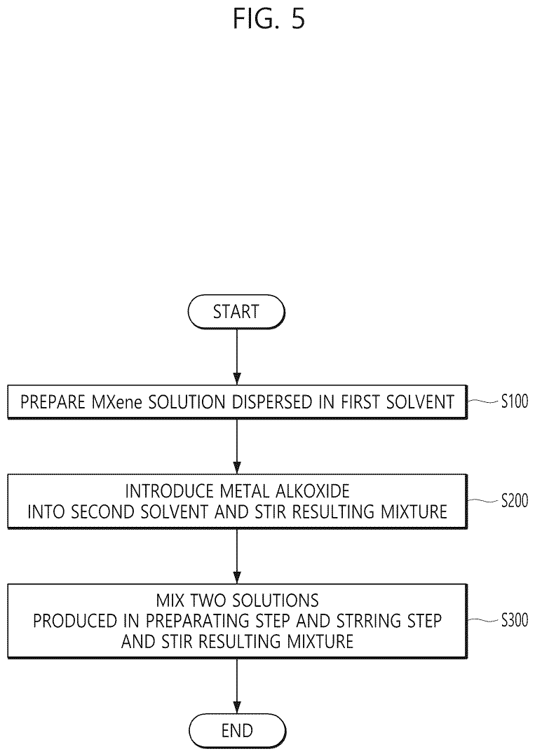

FIG. 5 is a flow chart illustrating a process of preparing a MXene surface-modified with a metal alkoxide according to one embodiment of the present invention.

### (1) Preparing Solution of MXene Dispersed in First Solvent (S100)

MXene is dispersed in a first solvent. The first solvent may include at least one selected from the group consisting of dimethyl sulfoxide (DMSO), dimethylformamide (DMF), N-methyl-2-pyrrolidone (NMP), propylene carbonate (PC), toluene, and hexane.

The concentration of the MXene solution in the preparing step (S100) of the MXene solution ranges from 0.01 to 100 mg/mL.

The MXene dispersed in the first solvent has already been described with reference to Chemical Formula 1 previously.

(2) Introducing Metal Alkoxide into Second Solvent and Stirring Resulting Mixture (S200)

A metal alkoxide is introduced into a second solvent and the resulting mixture is stirred. In this case, examples of the metal alkoxide are illustrated in FIG. 4, but are not necessarily limited thereto. It has been previously described that the alkyl group or aryl group of the metal alkoxide may be in the form of a carbon chain or a ring, and the metal alkoxide may further include an element selected from the group consisting of a halogen element, nitrogen, sulfur, and silicon.

When the amount of the MXene is x mg, the amount of metal alkoxide used in the stirring step (S200) is

$$\frac{1}{30} x μ l$$

to 100x μl. For example, when the amount of MXene is 30 mg, the appropriate amount of metal alkoxide is 1 μl to 3,000 μl.
(3) Reacting MXene with Alkoxide (S300)

After the two solutions produced in Steps (1) and (2) are mixed, the surface of the MXene is modified with the metal alkoxide when the resulting mixture is stirred.

In this case, the stirring time for the modification reaction is preferably in a range of 1 to 300 minutes. When the stirring time is less than 1 minute, it is insufficient for the surface functional group of the MXene to be substituted with an alkoxide, and when the stirring time exceeds 300 minutes, there is a risk in that MXene may be damaged by the alkoxide.

In addition, it is preferred that the stirring temperature for the modification reaction be under conditions where no heating is performed, for example, at 60° C. or lower, for example, room temperature. The reason is that when the stirring temperature exceeds 60° C., the MXene may be oxidized by the alkoxide.

Thereafter, the MXene modified with the metal alkoxide is transferred to a solvent in which the MXene is to be finally dispersed, and the MXene contained in the solvent is separated from the solvent using a centrifuge. In this case, the solvent in which the MXene is to be dispersed may be a polar organic solvent or a non-polar organic solvent, and the types thereof may be, as illustrated in FIG. 3, ethyl alcohol, isopropyl alcohol, acetonitrile, acetone, ethyl acetoacetate, diethyl ether, chloroform, toluene, and dichlorobenzene, or a combination thereof, but are not necessarily limited thereto.

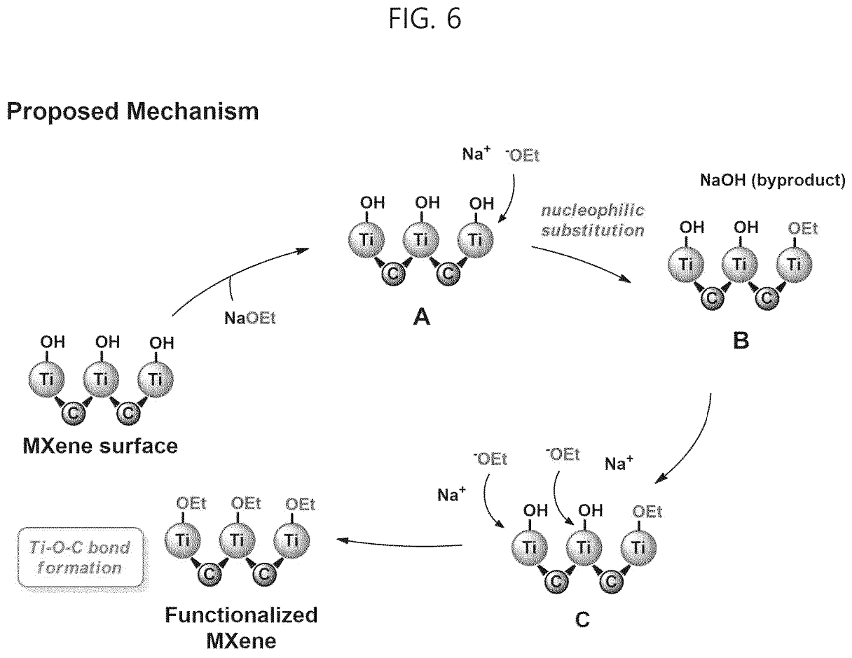

FIG. 6 is a conceptual view for describing a reaction mechanism for modifying the surface of a MXene with a metal alkoxide according to one embodiment of the present invention.

The chemical reaction scheme in FIG. 6 may be expressed as follows:

Ti—OH+NaOEt→Ti-OEt+NaOH (byproduct)

The process of preparing a 2D MXene from the MAX phase involves an etching process using strong acid, and as a result, an end group such as a hydroxyl group (OH) and an oxidation group (—O) is weakly bonded to the transition metal on the surface of the MXene and remains. Since the end group has a higher electronegativity than the transition metal, the end group attracts electrons from the transition metal on the surface of the MXene, and the transition metal becomes an electrophile which is relatively electron deficient.

Therefore, this mechanism proceeds via the Sn2 reaction (bimolecular nucleophilic substitution), which is a reaction between a nucleophile and an electrophile. The electron pair of the oxygen atom of ethoxide, a type of alkoxide group which is an electron-rich chemical species, acts as a nucleophile to attack the Ti element, which is an electrophile, present on the surface of MXene (FIG. 6A). At the same time, the hydroxyl group bonded to the surface of the Ti element is released together with the electron pair. The sodium ions added together with ethoxide are bonded to the released hydroxyl groups to produce sodium hydroxide (NaOH) as a byproduct (FIG. 6B). When the reaction in which ethoxide attacks other Ti elements in the MXene in addition to the Ti element is repeated several times (FIG. 6C), the ethoxide is bonded to the surface of the MXene as a ligand, so that the surface of the MXene is surface-modified with the ethoxide.

As a result of the Sn2 reaction, the electron pair of the oxygen atom of the ethoxide produces a strong covalent bond with the Ti element to form a Ti—O—C bond.

The concentration of a substrate and the concentration of a nucleophile affect the reaction rate in the Sn2 reaction. Therefore, the rate equation for the mechanism may be expressed as Rate=k[sub][nuc], where k is the reaction rate constant. The substrate may mean an electrophile.

In the case of the Sn2 reaction, a polar aprotic solvent or non-polar solvent, such as acetone, dimethylformamide (DMF), dimethyl sulfoxide (DMSO), toluene, and hexane is mainly used. Since the polar protic solvent may donate protons to a solution in which the reaction occurs, the nucleophile reacts with the protons of the solvent to interfere with the Sn2 reaction.

In addition, since the Sn2 reaction involves the addition of the nucleophile and the removal of the leaving group simultaneously in one step, the steric effect serves as an important factor. The steric hindrance of the substrate increases the energy of the transition state, increasing ΔG‡ and decreasing the reaction rate. Since the more reactive the nucleophile, the more unstable it is, the nucleophile is present in a high energy level state and ΔG‡ is reduced, thereby increasing the reaction rate. Therefore, negatively charged nucleophiles are more reactive than neutral nucleophiles, and the alkoxides disclosed in the present invention are negatively charged and highly reactive nucleophiles. In addition, the less steric hindrance the alkoxide has, the more easily the reaction occurs, so that the smaller the number of carbon atoms in the alkoxide group, the less steric hindrance there is, and the easier the reaction tends to be. Therefore, in the examples of this reaction, an ethoxide with two carbon atoms was used as an alkoxide.

In addition, since the rate of the Sn2 reaction is proportional to the concentration of the substrate and the concentration of the nucleophile, the reaction may be performed by various methods according to the concentration of the substrate and the concentration of the nucleophile.

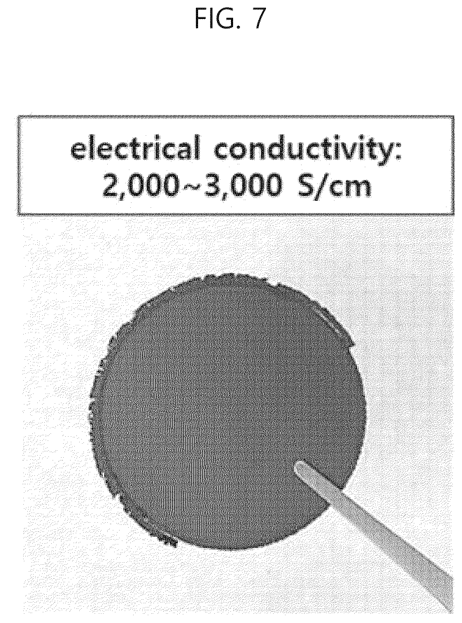

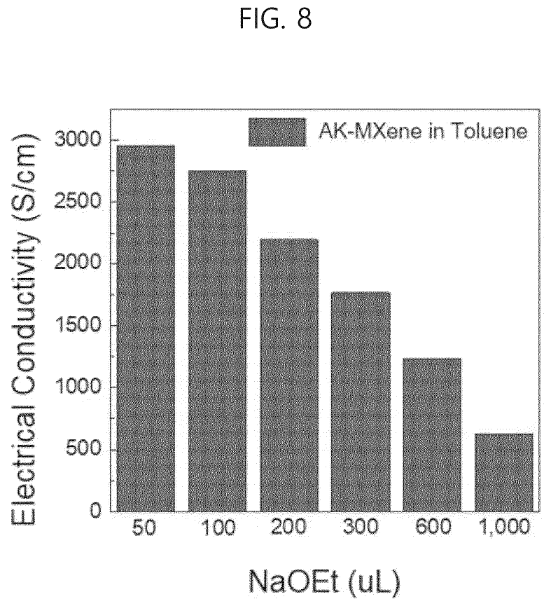

FIG. 7 is a photograph measuring the electrical conductivity of a MXene surface-modified with a metal alkoxide according to one embodiment of the present invention, and FIG. 8 is a graph illustrating the electrical conductivity of a MXene surface-modified with sodium ethoxide (NaOEt) according to one embodiment of the present invention, when the MXene is dispersed in a toluene solvent, according to the amount of NaOEt.

The MXene modified with the metal alkoxide according to the present invention may have an electrical conductivity of up to several thousands of S/cm. Referring to FIG. 7, the electrical conductivity of the MXene modified with the metal alkoxide was measured at 2,000 to 3,000 S/cm, but the electrical conductivity can be equal to or more than the value according to the amount of metal alkoxide. In the embodiment of FIG. 8, NaOEt was used as the metal alkoxide, and toluene was used as a solvent which disperses a MXene surface-modified with NaOEt.

Since NaOEt is a compound with low electrical conductivity, the smaller the amount of NaOEt used in the surface modification of MXene, the higher the electrical conductivity of MXene surface-modified with NaOEt. In contrast, as the amount of NaOEt used for the surface modification of MXene increases, the dispersibility of the NaOEt-surface-modified MXene based on non-polar solvents increases. Therefore, the dispersibility and electrical conductivity of MXene surface-modified with a metal alkoxide vary depending on the amount of metal alkoxide added. In the present invention, when a concentration of NaOEt of 50 L was used, it was found that the electrical conductivity of MXene surface-modified with NaOEt was 3,000 S/cm. In addition, as illustrated in FIGS. 1 and 3, it was found that the MXene surface-modified with NaOEt was well dispersed in a non-polar toluene solvent.

Although the range of MXene organic inks reported in prior studies and technologies in the related art is diverse, MXene needs to be dispersed in non-polar organic solvents in order for the MXene organic inks to be applied to a wider range of industry groups. However, it is currently known that the electrical conductivity of a MXene ink dispersed in a non-polar organic solvent is significantly low, ranging from tens to hundreds of S/cm. The MXene organic ink disclosed in the present invention has a high electrical conductivity of several thousands of S/cm even in a non-polar organic solvent such as toluene and dichlorobenzene, and the above value is up to several tens-fold higher than the electrical conductivity of the MXene inks reported in prior studies and technologies to date.

The MXene surface-modified with a metal alkoxide according to the present invention may be prepared as a MXene ink dispersed in a polar or non-polar organic solvent, and may be used in conductive ink-based industries such as the printing industry and the battery industry.

Meanwhile, the MXene surface-modified with the metal alkoxide according to the present invention may be prepared in the form of a conductive film and a polymer composite, and the conductive film and the polymer composite may be used to prepare an electromagnetic wave shielding material.

The MXene organic ink proposed by the present invention has high electrical conductivity at a level equal to that of metals. The higher the electrical conductivity, the better the electromagnetic wave shielding efficiency, so that an electromagnetic wave shielding material prepared using a MXene organic ink having high electrical conductivity at a level equal to that of metals exhibits excellent electromagnetic wave shielding performance. In addition, the MXene organic ink proposed by the present invention has excellent electrical conductivity, is lightweight, and has excellent processability using an aqueous solution. Therefore, the MXene organic ink proposed by the present invention can be used in a wide variety of applications, including not only electromagnetic wave shielding and electrode pattern materials that require electrical conductivity, but also secondary batteries or storage batteries, gas sensors, biosensors, and the like.

Hereinafter, an example of the MXene surface-modified with a metal alkoxide and a method for preparing the same according to the present invention will be described.

### EXAMPLE

### 1. Prepare Solution of MXene Dispersed in DMSO Solvent

MXene is dispersed in a dimethyl sulfoxide (DMSO) solution. The concentration of the solution is 1 mg/ml.

### 2. Introduce Sodium Ethoxide in Toluene and Stir Resulting Mixture

Sodium ethoxide is introduced into toluene and the resulting mixture is stirred. In this case, the amount of sodium ethoxide was 300 L.

3. React MXene with Ethoxide

After the two solutions produced in Nos. 1 and 2 above are mixed, when the resulting mixture is stirred at room temperature equal to or less than 60° C. for about 10 minutes, ethoxide is covalently bonded to the surface of MXene by the Sn2 reaction between ethoxide and MXene. Thereafter, the MXene modified with ethoxide is transferred to ethyl alcohol, which is a solvent in which the MXene is to be finally dispersed. The MXene contained in the ethyl alcohol solvent is separated into the solvent and MXene using a centrifuge. In this case, the solvents used in Steps 1 and 2, dimethyl sulfoxide (DMSO) and toluene, may be substituted with ethyl alcohol through the centrifugation process.

4. Obtain MXene Surface-Modified with Ethoxide

Through Nos. 1, 2, and 3, a MXene finally modified with ethoxide is obtained. In this case, the concentration of the MXene organic ink may be 0.01 to 100 mg/mL, and concentrations within this range are usually used.

The above-described content is merely illustrative, and various modifications may be made by a person having ordinary skill in the art to which the present invention pertains without departing from the scope and technical spirit of the described embodiments. The above-described embodiments may be implemented individually or in any combination.

### INDUSTRIAL APPLICABILITY

The present invention can be used in industrial fields related to MXenes or MXene applications.

1. A MXene surface-modified with a metal alkoxide, which is formed by surface-modifying a MXene represented by the following Chemical Formula 1 with a metal alkoxide,
wherein the alkoxide is covalently bonded to the surface of the MXene and is present as a ligand:
Mₙ₊₁Xₙ [Chemical Formula 1]
here, M is one or more transition metal elements selected from the group consisting of Sc, Ti, V, Cr, Mn, Y, Zr, Nb, Mo, Hf, and Ta, X is at least one of carbon and nitrogen, and n is an integer from 1 to 4.

2. The metal alkoxide-surface-modified MXene of claim 1, wherein the metal of the metal alkoxide comprises an alkali metal.

3. The metal alkoxide-surface-modified MXene of claim 1, wherein an alkyl group or aryl group of the alkoxide is in the form of a carbon chain or a carbon ring.

4. The metal alkoxide-surface-modified MXene of claim 3, wherein the alkoxide further comprises an element selected from the group consisting of halogen elements (F, Cl, Br, and I), nitrogen (N), sulfur (S), and silicon (Si).

5. A method for preparing a MXene surface-modified with a metal alkoxide, the method comprising:
preparing a MXene solution dispersed in a first solvent;
introducing a metal alkoxide into a second solvent and stirring the resulting mixture; and
modifying the surface of MXene with the metal alkoxide by mixing solutions produced in the preparing step and the stirring step and stirring the resulting mixture for a predetermined time or more.

6. The method of claim 5, wherein the first solvent and the second solvent comprise at least one selected from the group consisting of dimethyl sulfoxide (DMSO), dimethylformamide (DMF), N-methyl-2-pyrrolidone (NMP), propylene carbonate (PC), toluene, and hexane.

7. The method of claim 5, wherein after the modifying step, dispersing the metal alkoxide-surface-modified MXene in an organic solvent selected from the group consisting of ethyl alcohol, isopropyl alcohol, acetonitrile, acetone, ethyl acetoacetate, diethyl ether, chloroform, toluene, and dichlorobenzene to obtain a MXene organic ink is further performed.

8. The method of claim 5, wherein a concentration of the MXene solution in the preparing step ranges from 0.01 to 100 mg/mL.

9. The method of claim 5, wherein when an amount of the MXene is x mg, an amount of metal oxide used in the stirring step is
$$\frac{1}{30} x μ l$$
to 100x μl.

10. The method of claim 5, wherein the stirring time in the stirring step ranges from 1 to 300 minutes, and the stirring temperature is 60° C. or less.

11. A MXene organic ink comprising: the metal alkoxide-surface-modified MXene of claim 1; and
an organic solvent in which the MXene is dispersed, wherein the organic solvent is selected from the group consisting of ethyl alcohol, isopropyl alcohol, acetonitrile, acetone, ethyl acetoacetate, diethyl ether, chloroform, toluene, and dichlorobenzene.

12. The MXene organic ink of claim 11, wherein a concentration of the MXene organic ink is 0.01 to 100 mg/mL.

13. A method for preparing a MXene organic ink, the method comprising: dispersing the metal alkoxide-surface-modified MXene prepared by the method described in claim 5 in an organic solvent,
wherein the organic solvent is selected from the group consisting of ethyl alcohol, isopropyl alcohol, acetonitrile, acetone, ethyl acetoacetate, diethyl ether, chloroform, toluene, and dichlorobenzene.
